(19) United States
(12) Patent Application Publication
(10) Pub. No.: US 2013/0037406 A1
(43) Pub. Date: Feb. 14, 2013

(54) Sputtering apparatus

(71) Applicant: Myung-Soo Huh, Yongin-city (KR)

(72) Inventor: Myung-Soo Huh, Yongin-city (KR)

(21) Appl. No.: 13/506,235

(22) Filed: Apr. 4, 2012

(30) Foreign Application Priority Data
Aug. 10, 2011 (KR) 10-2011-0079675

(51) Int. Cl. C23C 14/34; C23C 14/08; C23C 14/35

(52) U.S. Cl. 204/298.09; 204/298.02; 204/298.16; 204/298.17

(57) ABSTRACT

A sputtering device for depositing a deposition material from a deposition source to a deposition target, wherein a sputtering pressure between the deposition source and the deposition target is from about 6.70×10⁻² Pa to about 1.34×10⁻¹ Pa.

### CROSS-REFERENCE TO RELATED APPLICATION

This application claims priority to and the benefit of Korean Patent Application No. 10-2011-0079675 filed in the Korean Intellectual Property Office on Aug. 10, 2011, the entire content of which is incorporated herein by reference.

### BACKGROUND

1. Field

The described technology relates generally to a sputtering apparatus.

2. Description of the Related Art

A sputtering apparatus is an apparatus for forming a deposition layer at a deposition target.

A conventional sputtering device forms a metal oxide layer at a deposition target using a reactive sputtering method when depositing the metal oxide layer as a deposition layer. When the metal oxide layer is deposited to the deposition target using the reactive sputtering method, a sputtering pressure between the deposition source and the deposition target is set to about 6.7×10⁻¹ Pa. In this case, a mean free path of particles discharged from the deposition source is about 5 cm between the deposition source and the deposition target, so that most of the particles collide with each other before reaching the deposition target, and thus, kinetic energy is reduced. Accordingly, a density of the deposition layer formed at the deposition target may be deteriorated or reduced.

In particular, when the deposition target is a substrate including an organic material, the substrate cannot be heated to a high temperature due to thermal vulnerability, and thus, when the sputtering pressure is set to about 6.7×10⁻¹ Pa, the density of the deposition layer formed at the substrate including the organic material may be reduced or deteriorated.

The above information disclosed in this Background section is only for enhancement of understanding of the background of the described technology, and therefore, it may contain information that does not constitute prior art and that is already known in this country to a person of ordinary skill in the art.

### SUMMARY

Embodiments of the present invention provide a sputtering device that can improve a density of a deposition layer formed at a deposition target.

One aspect of embodiments of the present invention provides a sputtering device for depositing a deposition material from a deposition source to a deposition target, wherein a sputtering pressure between the deposition source and the deposition target is from about 6.70×10⁻² Pa to about 1.34×10⁻¹ Pa.

The sputtering device may include a backing plate contacting the target, and a magnetic substance contacting the backing plate, and the backing plate may be between the deposition source and the magnetic substance.

A magnetic flux density at a surface of the deposition source and corresponding to the magnetic substance may be from about 1.17×10³ Gauss to about 1.70×10³ Gauss.

The magnetic substance may include a plurality of magnetic substances, the sputtering device may further include a cooling path for cooling water, and the cooling path may be located between neighboring magnetic substances among the plurality of magnetic substances.

The deposition material may include metal oxide.

The metal oxide may include at least one selected from the group consisting of ITO, tin oxide (SnOx), and zinc oxide (ZnO).

The deposition source and the deposition target may be separated by about 10 cm.

The sputtering device may be configured to produce the sputtering pressure between the deposition source and the deposition target of about 6.70×10⁻² Pa.

The sputtering device may be configured to deposit the deposition material to the deposition target at a temperature that is lower than about 150° C.

According to exemplary embodiments of the present invention, a sputtering device is provided, by which a density of a deposition layer formed at a deposition target may be improved.

### BRIEF DESCRIPTION OF THE DRAWINGS

FIG. 1 shows a sputtering apparatus according to an exemplary embodiment of the present invention.

FIG. 2 and FIG. 3 are graphs corresponding to experiments involving a sputtering apparatus according to the exemplary embodiment shown in FIG. 1.

FIGS. 4(a) and 4(b) are photographs that show a first experimental example of the exemplary embodiment shown in FIG. 1.

FIGS. 5(a) and 5(b) are photo graphs that show a second experimental example of the exemplary embodiment shown in FIG. 1.

### DETAILED DESCRIPTION

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In order to elucidate embodiments of the present invention, some of the parts that are not related to the description may be omitted. Like reference numerals designate like elements throughout the specification.

In addition, the size and thickness of each component shown in the drawings may be arbitrarily shown for understanding and ease of description, but the present invention is not limited thereto.

Further, unless explicitly described to the contrary, the word “comprise” and variations such as “comprises” or “comprising,” will be understood to imply the inclusion of stated elements, but not necessarily to the exclusion of any other elements. It will be understood throughout the specification that when an element is referred to as being “on” another element, it can be directly on the other element, or one or more intervening elements may also be present.

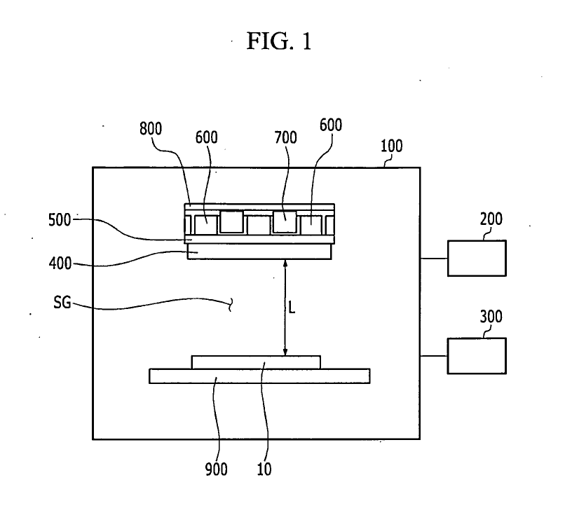

Hereinafter, a sputtering apparatus according to an exemplary embodiment of the present invention will be described with reference to FIG. 1 to FIG. 3.

FIG. 1 shows a sputtering apparatus according to an exemplary embodiment of the present invention.

As shown in FIG. 1, the sputtering apparatus according to the present exemplary embodiment forms a deposition layer on a deposition target 10, and includes a chamber 100, a gas supply unit 200, an exhaust pump 300, a deposition source 400, a backing plate 500, a magnetic substance 600, a cooling path 700, an electrode 800, and a holder 900.

The chamber 100 is used to create a vacuum during a sputtering process.

The gas supply unit 200 may supply an inert gas such as, for example, argon (Ar) gas, and/or oxygen (O₂) gas into the chamber 100.

The exhaust pump 300 lowers an internal pressure of the chamber 100.

The deposition source 400 includes metal that constitutes a deposition material to be included in a deposition layer that is to be formed on a deposition target 10. A distance L between the deposition source 400 and the deposition target 10 may be, for example, about 10 cm.

The backing plate 500 is located between the deposition source 400 and the magnetic substance 600, and contacts the deposition source 400.

The magnetic substance 600 is arranged opposite to the deposition source 400, with the backing plate 500 therebetween, and contacts the backing plate 500. The magnetic substance 600 is adjacent to the deposition source 400 and contacts the backing plate 500 so that the intensity of the magnetic field created on the surface of the deposition source 400 is increased. Accordingly a sputtering pressure of the sputtering space SG between the deposition source 400 and the deposition target 10 is decreased. A plurality of the magnetic substance 600 is provided, and the plurality of magnetic substances 600 contact the deposition source 400.

The cooling path 700 is located between neighboring magnetic substances 600 among the plurality of magnetic substances 600, and forms a channel for cooling water. When the sputtering is performed, the cooling water flowing through the cooling path 700 prevents the temperature of the deposition source 400 from increasing beyond a temperature (e.g., a predetermined temperature).

The electrode 800 is located opposite the backing plate 500, with respect to the magnetic substance 600 and the cooling path 700 interposed therebetween.

The deposition target 10 is supported by the holder 900.

Hereinafter, an operation of the sputtering device of the present exemplary embodiment will be described.

The deposition target 10 is supported by the holder 900, and inert gas such as, for example, argon (Ar) is supplied into the chamber 100 in a vacuum state with a high voltage between the holder 900 and the backing plate 500. The argon (Ar) may be, for example, in a plasma state, that is, the argon (Ar) may be formed into argon ions (Ar⁺) in the sputtering space SG between the deposition source 400 and the deposition target 10, and the argon ions (Ar⁺) can collide with the deposition source 400, and thus a metallic material is discharged from the deposition source 400 into the sputtering space SG. The metallic material discharged into the sputtering space SG moves toward the deposition target 10 and reacts with oxygen (O₂) gas supplied into the chamber 100 so that a deposition material including a metal oxide is deposited to the deposition target 10, and accordingly, a deposition layer is formed on the deposition target 10.

In this case, a magnetic flux density at the surface of the deposition source 400 and caused by the magnetic substance 600 that is adjacent to the deposition source 400 is for example, from about 1.17×10³ Gauss to about 1.70×10³ Gauss, and accordingly, the sputtering pressure in the sputtering space SG between the deposition source 400 and the deposition target 10 is set to be from about 6.70×10⁻² Pa to about 1.34×10⁻¹ Pa. Since the sputtering pressure of the sputtering space SG is set to be from about 6.70×10⁻² Pa to about 1.34×10⁻¹ Pa, a mean free path of the metallic materials discharged from the deposition source 400 is improved so that a density of the deposition layer deposited at the deposition target 10 can be increased.

Hereinafter, a reason why the sputtering pressure of the sputtering space SG is set to be from about 6.70×10⁻² Pa to about 1.34×10⁻¹ Pa will be described in further detail.

Equation 1 below is a formula showing a relationship between the sputtering pressure and kinetic energy of the sputtered particles (e.g., metallic materials) according to embodiments of the present invention.

$${E}_{F} = ( {E}_{0} - {k}_{B} {T}_{G} ) exp [ N ln ( \frac{{E}_{f}}{{E}_{i}} ) ] + {k}_{B} {T}_{G} \qquad [ Equation 1 ]$$

Here, E_{F} denotes energy of the sputtered particles reaching the substrate, which is the deposition target (e.g., the deposition target 10), E₀ denotes energy of the particles discharged from the deposition source surface (e.g., the surface of deposition source 400), T_{G} denotes a temperature of the sputtering gas e.g., (Ar gas), E_{f}/Eᵢ denotes a ratio of energies before and after collision between the particles in the sputtering space (e.g., the sputtering space SG), N denotes the number of collisions in the gas injected into the chamber (e.g., the chamber 100), and k_{B} denotes the Boltzmann constant.

In addition, N and E_{f}/Eᵢ of Equation 1 can be respectively represented as Equation 2 and Equation 3, which are shown below.

N=(dP_{w}σ)/(k_{B}T_{G}) [Equation 2]

Here, d denotes a moving distance of the particle, Pw denotes a sputtering pressure, and σ denotes a collision cross-section of the particle.

E_{f}/Eᵢ=1−2η/(1+η)² [Equation 3]

Here, η denotes an atomic weight ratio of the collided particles.

Thus, a kinetic energy ratio when the argon (Ar) particles, i.e., the sputtering gas, reaches the substrate may be about 65% higher when the sputtering pressure is 6.7×10⁻² Pa than it is when the sputtering pressure is 6.7×10⁻¹ Pa, as shown through calculation using Equations 1, 2, and 3, and accordingly, the density of the deposition layer deposited to the deposition target (e.g., deposition target 10) can be increased using the kinetic energy of the sputtering particles if the sputtering pressure is reduced by about a factor of 10.

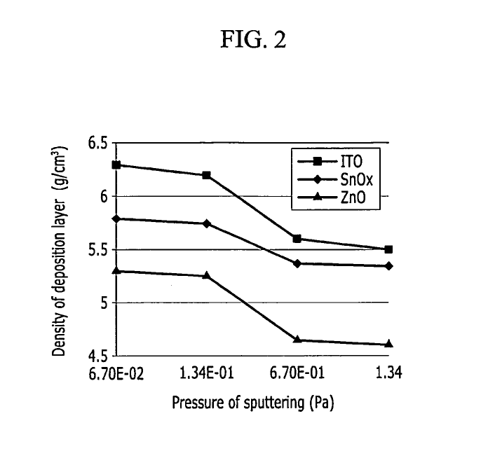

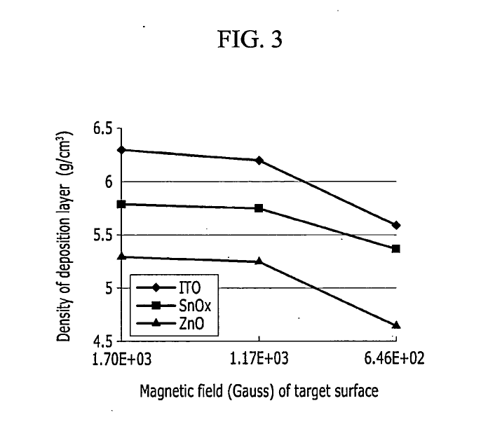

FIG. 2 and FIG. 3 are graphs for illustrating experiments corresponding to the sputtering device according to the present exemplary embodiment.

Thus, a density of the deposition layer deposited to the deposition target (e.g., deposition target 10), which varies according to the sputtering pressure, is shown. Here, the deposition layer includes at least one of ITO, tin oxide (SnOx), or zinc oxide (ZnO), and, as shown in the graph of FIG. 2, the density of the deposition layer deposited to the deposition target was critically increased when the sputtering pressure was from about 6.70×10⁻² Pa to about 1.34×10⁻¹ Pa. That is, the density of the deposition layer was critically increased when the sputtering pressure was set to a limited range, that is, from about 6.70×10⁻² Pa to about 1.34×10⁻¹ Pa, and accordingly, the sputtering device of the present embodiment has a sputtering pressure of the sputtering space SG set to from about 6.70×10⁻² Pa to about 1.34×10⁻¹ Pa.

Further, it might not be easy to set the sputtering pressure to from about 6.70×10⁻² Pa to about 1.34×10⁻¹ Pa with a sputtering method using a conventional sputtering device, and thus, a method for increasing the magnetic flux density at the deposition source surface (e.g., the deposition source surface 400) by at least a factor of two was created. Thus, an experiment on the relationship between density of the deposition layer deposited to the deposition target (e.g., the deposition target 10) and the magnetic flux density of the deposition source surface (e.g., the surface of the deposition source 400), i.e., a magnetic field on the deposition source surface, is shown in the graph of FIG. 3 which shows that the density of the deposition layer deposited to the deposition target (e.g., the deposition target 10) was critically increased when the magnetic flux density at the surface of the deposition source 400 was from about 1.17×10³ Gauss to about 1.70×10³ Gauss. That is, the density of the deposition layer was critically increased when the magnetic flux density of the surface of the deposition source 400 having a limited range was from about 1.17×10³ Gauss to about 1.70×10³ Gauss, and thus, the sputtering device of the present exemplary embodiment has the magnetic flux density of the surface of the deposition source 400 set to from about 1.17×10³ Gauss to about 1.70×10³ Gauss.

As described above, the sputtering device according to the present exemplary embodiment increases the density of the deposition layer deposited to the deposition target 10 by controlling the sputtering pressure of the sputtering space SG.

In particular, the sputtering device according to the present exemplary embodiment increases the density of the deposition layer formed at the deposition target 10 even when a deposition material forming the deposition layer is deposited to the deposition target 10 at a temperature lower than 150° C., because the deposition target 10 includes an organic material, and because the density of the deposition layer is dependent on the sputtering pressure of the sputtering space SG.

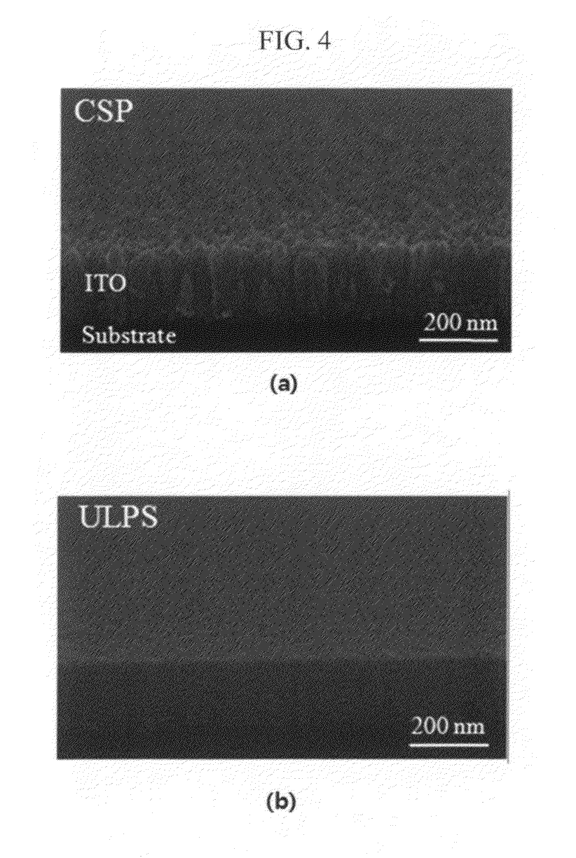

Hereinafter, a first experimental example corresponding to the present embodiment will be described with reference to FIG. 4.

FIG. 4 illustrates photos for explaining the first experimental example of the present embodiment. FIG. 4(a) is a photo showing a deposition layer formed through a first comparative example, and FIG. 4(b) shows a deposition layer formed through the first experimental example.

As shown in FIG. 4(a), an ITO deposition source sintered with a ratio of 9:1 of In₂O₃ (99.99%) and SnO₂ (99.9%) was used as a deposition source in the first comparative example (CSP), and a substrate and the deposition source were separated from each other with a distance of 10 cm. Only argon (Ar) was used as the sputtering gas and the sputtering pressure was fixed at 6.7×10⁻¹ Pa by controlling a flow rate of Ar, and then a cross-section of an ITO thin film formed on the substrate was observed. As shown in FIG. 4(a), it was observed that a coarse columnar structure was formed in the ITO thin film formed by the first comparative example.

As shown in FIG. 4(b), in the first experimental example (ULPS), an ITO deposition source sintered with a ratio of 9:1 of In₂O₃ (99.99%) and SnO₂ (99.9%) was used and the substrate (e.g., deposition target 10) and the deposition source (e.g., deposition source 400) were separated from each other with a distance (e.g., L) of 10 cm. Only argon (Ar) was used as the sputtering gas, and the sputtering pressure was fixed at 6.7×10⁻² Pa by controlling a flow rate of Ar, and then a cross-section of an ITO thin film formed at the substrate was observed

As shown in FIG. 4(b), the ITO thin film formed through the first experimental example has delicate and dense tissues.

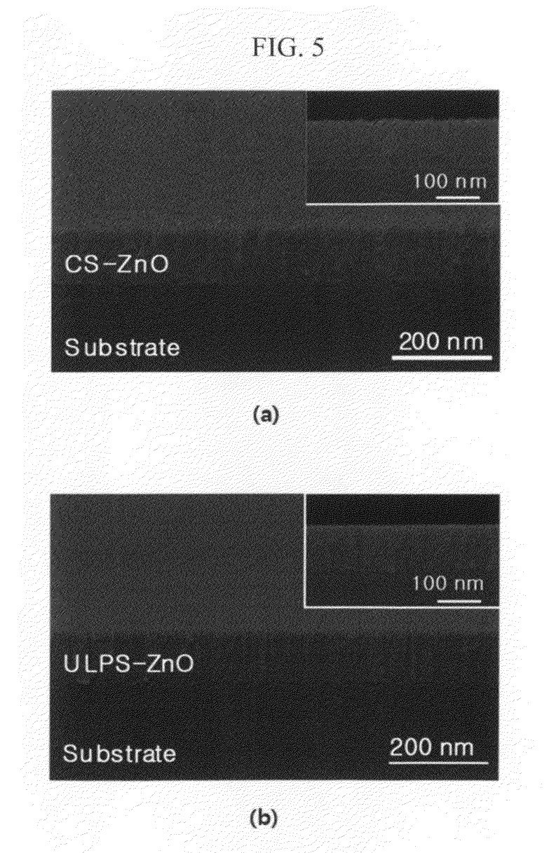

A second experimental example will be described with reference to FIG. 5.

FIG. 5 illustrates photos for explaining the second experimental example of the present embodiment. FIG. 5(a) is a photo showing a deposition layer formed through a second comparative example, and FIG. 5(b) shows a deposition layer formed through the second experimental example.

As shown in FIG. 5(a), a ZnO (99.99%) deposition source was used as a deposition source in the second comparative example (CS-ZnO) and a substrate and the deposition source were separated from each other with a distance of 10 cm. Only argon (Ar) was used as the sputtering gas and the sputtering pressure was fixed at 6.7×10⁻¹ Pa by controlling a flow rate of Ar, and then a cross-section of a ZnO thin film formed at the substrate was observed. As shown in FIG. 5(a), it was observed that a coarse columnar structure was formed in the ZnO thin film formed by the second comparative example.

As shown in FIG. 5(b), in the second experimental example (ULPS-ZnO), a ZnO (99.99%) deposition source was used as a deposition source (e.g., deposition source 400), and the substrate (e.g., the deposition target 10) and the deposition source (e.g., the deposition source 400) were separated from each other by a distance (e.g., L) of 10 cm. Only argon (Ar) was used as the sputtering gas, and the sputtering pressure was fixed at 6.7×10⁻² Pa by controlling a flow rate of Ar, and then a cross-section of an ZnO thin film formed at the substrate was observed

As shown in FIG. 5(b), it was observed that the ZnO thin film formed through the second experimental example had delicate and dense tissues.

While this disclosure has been described in connection with what is presently considered to be practical exemplary embodiments of the present invention, it is to be understood that the present invention is not limited to the disclosed embodiments, but, on the contrary, is intended to cover various modifications and equivalent arrangements included within the spirit and scope of the appended claims and their equivalents.

What is claimed is:

1. A sputtering device for depositing a deposition material from a deposition source to a deposition target,
wherein a sputtering pressure between the deposition source and the deposition target is from about 6.70×10⁻² Pa to about 1.34×10⁻¹ Pa.

2. The sputtering device of claim 1, wherein the sputtering device is configured to deposit the deposition material to the deposition target at a temperature that is lower than about 150° C.

3. The sputtering device of claim 1 comprising:
a backing plate contacting the target; and
a magnetic substance contacting the backing plate,
wherein the backing plate is between the deposition source and the magnetic substance.

4. The sputtering device of claim 3, wherein the sputtering device is configured to deposit the deposition material to the deposition target at a temperature that is lower than about 150° C.

5. The sputtering device of claim 3, wherein a magnetic flux density at a surface of the deposition source and corresponding to the magnetic substance is from about 1.17×10³ Gauss to about 1.70×10³ Gauss.

6. The sputtering device of claim 5, wherein the sputtering device is configured to deposit the deposition material to the deposition target at a temperature that is lower than about 150° C.

7. The sputtering device of claim 3, wherein the magnetic substance comprises a plurality of magnetic substances, and
wherein the sputtering device further comprises a cooling path for cooling water, the cooling path being located between neighboring magnetic substances among the plurality of magnetic substances.

8. The sputtering device of claim 7, wherein the sputtering device is configured to deposit the deposition material to the deposition target at a temperature that is lower than about 150° C.

9. The sputtering device of claim 1, wherein the deposition material comprises metal oxide.

10. The sputtering device of claim 9, wherein the sputtering device is configured to deposit the deposition material to the deposition target at a temperature that is lower than about 150° C.

11. The sputtering device of claim 9, wherein the metal oxide comprises at least one selected from the group consisting of ITO, tin oxide (SnOx), and zinc oxide (ZnO).

12. The sputtering device of claim 11, wherein the sputtering device is configured to deposit the deposition material to the deposition target at a temperature that is lower than about 150° C.

13. The sputtering device of claim 1, wherein the deposition source and the deposition target are separated by about 10 cm.

14. The sputtering device of claim 13, wherein the sputtering device is configured to deposit the deposition material to the deposition target at a temperature that is lower than about 150° C.

15. The sputtering device of claim 1, wherein the sputtering device is configured to produce the sputtering pressure between the deposition source and the deposition target of about 6.70×10⁻² Pa.

16. The sputtering device of claim 15, wherein the sputtering device is configured to deposit the deposition material to the deposition target at a temperature that is lower than about 150° C.
